(19) United States
(12) Patent Application Publication
(10) Pub. No.: US 2012/0101750 A1
(43) Pub. Date: Apr. 26, 2012

(54) DEVICE FOR MEASURING POWER SUPPLY EFFICIENCY AND METHOD FOR USING SAME

(75) Inventors: CHUN-PO CHEN, Tu-Cheng (TW); CHIA-MING YEH, Tu-Cheng (TW)

(73) Assignee: HON HAI PRECISION INDUSTRY CO., LTD., Tu-Cheng (TW)

(21) Appl. No.: 12/980,271

(22) Filed: Dec. 28, 2010

(30) Foreign Application Priority Data
Oct. 20, 2010 (TW) 99135653

(51) Int. Cl. G01R 21/06; G06F 19/00

(52) U.S. Cl. 702/60

(57) ABSTRACT

Measurement of power efficiency of a power supply device includes detecting a value of a current input to the power supply device and transmitting the input current value to a processor. A pulse width modulation (PWM) controller detects a value of a current output by the power supply device and transmits the output current value to the processor. A value of the power efficiency of the power supply device is calculated according to the input current value and the output current value.

### BACKGROUND

1. Technical Field

The present disclosure relates to power supply devices, and particularly to a device for measuring power supply efficiency and a method for using the same.

2. Description of Related Art

Many power supply devices of electronic devices include buck converters. These buck converters can decrease excessively high voltages input to the power supply devices, such as voltages provided by mains power, and thereby regulate the input voltages within ranges suitable for use. However, power efficiencies of the buck converters, that is, ratios of power output to input, are generally difficult to determine, which may adversely affect working status detection for the electronic devices using the buck converters.

Therefore, there is room for improvement within the art.

### BRIEF DESCRIPTION OF THE DRAWINGS

Many aspects of the present device and method for using the same can be better understood with reference to the following drawings. The components in the various drawings are not necessarily drawn to scale, the emphasis instead being placed upon clearly illustrating the principles of the present disclosure. Moreover, in the drawings, like reference numerals designate corresponding parts throughout the figures.

FIG. 1 is a circuit diagram of a device for measuring power supply efficiency, according to an exemplary embodiment.

FIG. 2 is a flowchart of a method for using one exemplary embodiment of a device for measuring power supply efficiency such as, for example, that shown in FIG. 1.

### DETAILED DESCRIPTION

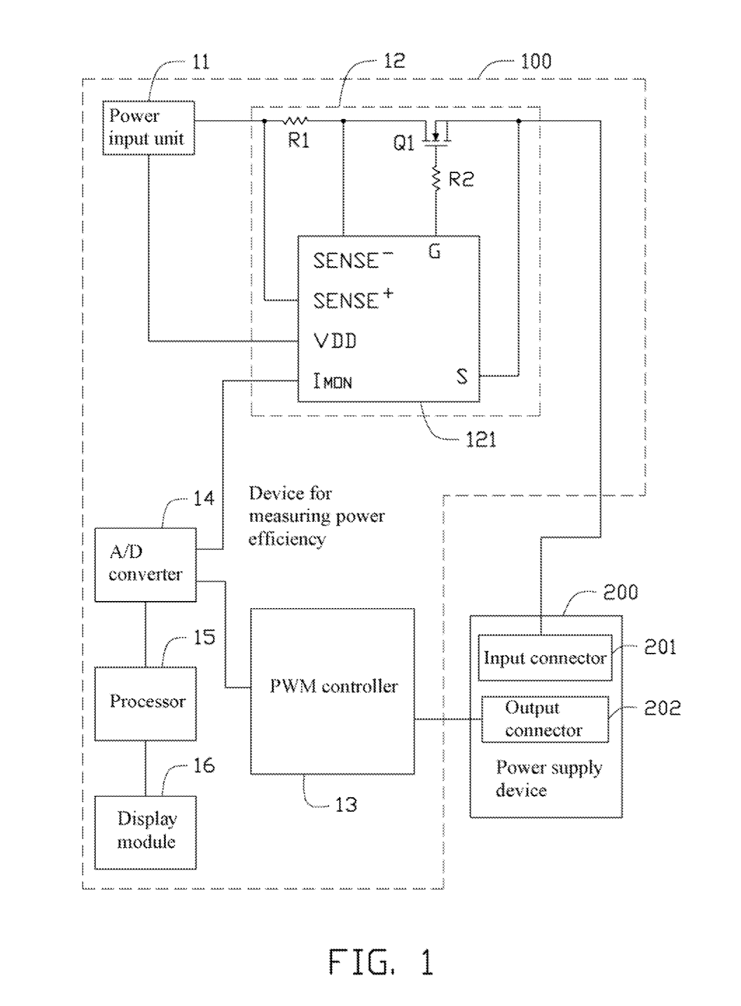

FIG. 1 shows a device 100, according to an exemplary embodiment. The device 100 is used to measure a power efficiency η of a power supply device 200, that is, a ratio of power output by the power supply device 200 to input to the power supply device 200. The power supply device 200 can be a common power supply device that uses at least one buck converter (not shown). Both the device 100 and the power supply device 200 can be installed in a common electronic device (not shown), such as a personal computer (PC). The device 100 includes a power input unit 11, a hot-swap control unit 12, a pulse width modulation (PWM) controller 13, an analog/digital (A/D) converter 14, a processor 15, and a display module 16. The power supply device 200 has an input connector 201 and an output connector 202.

The power input unit 11 is an electric connection device, such as a plug or an adapter, and can be connected to an external power supply (not shown), such as a battery or mains power. The hot-swap control unit 12 includes a hot-swap controller 121, a first resistor R1, a second resistor R2, and a metal-oxide-semiconductor field effect transistor (MOSFET) Q1, wherein the MOSFET Q1 is an N-channel MOSFET. The hot-swap controller 121 can be an LTC4218 integrated circuit (IC), which includes a voltage input pin VDD, a non-inverting sensing pin SENSE+, an inverting sensing pin SENSE−, a gate pin G, a source pin S, and a current output pin I_{MON}. The power input unit 11 is connected to the voltage input pin VDD. The first resistor R1 has one end connected to the power input unit 11 and another end connected to a drain of the MOSFET Q1. The non-inverting sensing pin SENSE+ and the inverting sensing pin SENSE− are respectively connected to the two ends of the first resistor R1. The second resistor R2 has one end connected to a gate of the MOSFET Q1 and another end connected to the gate pin G. A source of the MOSFET Q1 is connected to the source pin S, and is also connected to the input connector 201 of the power supply device 200. The current output pin I_{MON} is connected to the A/D converter 14.

The PWM controller 13 can be an ISL6333 IC. The PWM controller 13 is connected to the output connector 202 of the power device 200 and the A/D converter 14. The processor 15 is connected to the A/D converter 14, and the display module 16 is connected to the processor 15. The processor 15 and the display module 16 can be independent microprocessor and display, and can also be respectively integrated with a central processing unit (CPU) and a display of the electronic device using the device 100 and the power supply device 200.

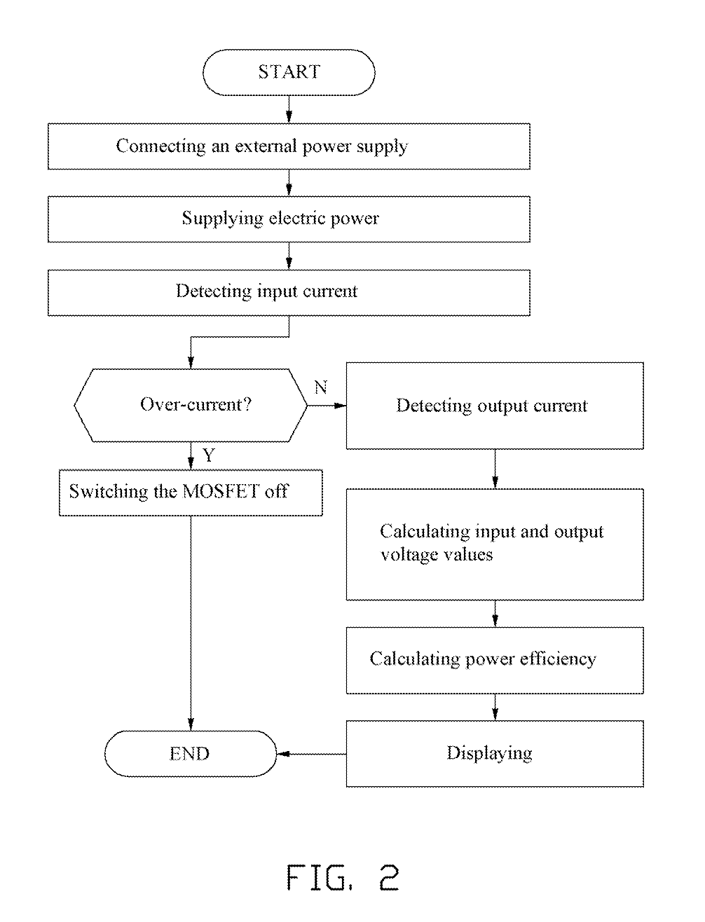

FIG. 2 shows a method for using the device 100 to measure the power efficiency η of the power supply device 200, according to an exemplary embodiment, as follows.

The power input unit 11 is connected to an external power supply (not shown), such as a battery or mains power, and a voltage of the external power supply is transmitted to the drain of the MOSFET Q1 through the resistor R1. At the same time, the voltage of the external power supply is also input to the voltage input pin VDD of the hot-swap controller 121 to switch the hot-swap controller 121 on. The hot-swap controller 121 generates a voltage on the gate pin G, and the voltage is applied to the MOSFET Q1 through the resistor R2 to switch the MOSFET Q1 on. Thus, the drain and the source of the MOSFET Q1 are connected to each other, and the power input unit 11 is connected to the input connector 201 of the power supply device 200 via the resistor R1 and the MOSFET Q1. In this way, the voltage of the external power supply is input to the power supply device 200 via the power input unit 11 and the hot-swap control unit 12, and thus electric power of the external power supply is provided to the power supply device 200. The power supply device 200 provides the electric power to inner circuitry (not shown) of the electronic device via the output connector 202.

When the voltage of the external power supply is input to the power supply device 200 via the power input unit 11 and the hot-swap control unit 12, a current is generated through the resistor R1 and the drain and the source of the MOSFET Q1 and input to the power supply device 200 via the input connector 201. When the current passes through the resistor R1, the hot-swap controller 121 samples the current using the non-inverting sensing pin SENSE+ and the inverting sensing pin SENSE− to detect a value I_{I} of the current, and transmits the current value I_{I} to the A/D converter 14 using the current output pin I_{MON}. The A/D converter 14 converts the current value I_{I} to a digital signal and transmits the digital signal of the current value I_{I} to the processor 15. According to known characters of LTC4218 IC, upon receiving the current value I_{I}, the processor 15 can calculate a value V_{I} of a voltage input to the power supply device 200 according to the current value I_{I}. Thus, the processor 15 can calculate a value P_{I} of power input to the power supply device 200 according to the formula: P_{I}=V_{I}×I_{I}.

When the power supply device 200 provides the electric power to the electronic device via the output connector 202, the PWM controller 13 detects a value I_{O} of a current output by the output connector 201 and transmits the current value I_{O} to the A/D converter 14. The A/D converter 14 converts the current value I_{O} to a digital signal and transmits the digital signal of the current value I_{O} to the processor 15. According to known characters of ISL6333 IC, upon receiving the current value I_{O}, the processor 15 can calculate a value V_{O} of a voltage output by the power supply device 200 according to the current value I_{O}. Thus, the processor 15 can calculate a value P_{O} of power output by the power supply device 200 according to the formula: P_{O}=V_{O}×I_{O}.

Finally, the processor 15 calculates the power efficiency η of the power supply device 200 according to the formula: η=P_{O}/P_{I}. The calculated value of η is displayed by the display module 16. The values I_{I}, V_{I}, U_{I}, I_{O}, V_{O}, U_{O} can also be displayed by the display module 16.

In this exemplary embodiment, since the power input unit 11 is connected to the power supply device 200 through the hot-swap control unit 12, the power supply device 200 can be safely separated from the external power supply by means of hot-swap. Furthermore, when the input current value I_{I} exceeds a predetermined value, the hot-swap controller 121 can automatically switches the MOSFET Q1 off using the gate pin G or the source pin S, such that the input current is prevented from being provided to the power supply device 200. In this way, the device 100 can protect the power supply device 200 from over-current. Additionally, the A/D converter 14 can also be integrated with the processor 15.

In this exemplary embodiment, the device 100 can measure and display the value of the efficiency of the power supply device 200. Accurate working status of the electronic device is readily and accurately available. Furthermore, the device 100 can also enable the power supply device 200 to be hot-swapped and protect the power supply 200 from over-current.

It is to be further understood that even though numerous characteristics and advantages of the present embodiments have been set forth in the foregoing description, together with details of structures and functions of various embodiments, the disclosure is illustrative only, and changes may be made in detail, especially in matters of shape, size, and arrangement of parts within the principles of the present invention to the full extent indicated by the broad general meaning of the terms in which the appended claims are expressed.

What is claimed is:

1. A device for measuring power efficiency of a power supply device, comprising:
a hot-swap control unit connected to the power supply device;
a pulse width modulation (PWM) controller connected to the power supply device; and
a processor connected to the hot-swap control unit and the PWM controller; wherein the hot-swap control unit detects a value of a current input to the power supply device and transmits the input current value to the processor, the PWM controller detects a value of a current output by the power supply device and transmits the output current value to the processor, and the processor calculates a value of the power efficiency of the power supply device according to the input current value and the output current value.

2. The device as claimed in claim 1, wherein the processor calculates values of a voltage input to the power supply device and a voltage output by the power supply device according to the input current value and the output current value, and further calculates the power efficiency of the power supply device according to the input voltage value, the input current value, the output voltage value, and the output current value.

3. The device as claimed in claim 1, further comprising a power input unit connected to the hot-swap control unit, wherein external electric power is input to the power supply device through the power input unit and the hot-swap control unit.

4. The device as claimed in claim 3, wherein the hot-swap control unit includes a hot-swap controller and a metal-oxide-semiconductor field effect transistor (MOSFET); the hot-swap controller including a voltage input pin, a gate pin, and a current output pin; the power input unit connected to the voltage input pin, a drain of the MOSFET connected to the power input unit, a source of the MOSFET connected to the power supply device, and a gate of the MOSFET connected to the gate pin; wherein when a voltage is applied to the voltage input pin through the power input unit, the hot-swap controller is switched on and switches the MOSFET on using the gate pin to connect the power input unit to the power supply device, such that the voltage generates the current input to the power supply device.

5. The device as claimed in claim 4, wherein the hot-swap control unit further includes a first resistor, and the hot-swap controller further includes a non-inverting sensing pin, an inverting sensing pin, and a current output pin; the first resistor having one end connected to the power input unit and another end connected to a drain of the MOSFET, the non-inverting sensing pin and the inverting sensing pin respectively connected to the two ends of the first resistor, and the current output pin connected to the processor; the hot-swap controller detecting the value of the current input to the power supply device using the non-inverting sensing pin and the inverting sensing pin, and transmitting the input current value to the processor using the current output pin.

6. The device as claimed in claim 5, wherein the hot-swap control unit further includes a second resistor, one end of the second resistor connected to the gate of the MOSFET and another end of the second resistor connected to the gate pin of the hot-swap controller.

7. The device as claimed in claim 6, wherein the hot-swap controller further includes a source pin connected to the source of the MOSFET, when the value of the current input to the power supply device exceeds a predetermined value, the hot-swap controller switches the MOSFET off using the gate pin or the source pin.

8. The device as claimed in claim 4, wherein the hot-swap controller is an LTC4218 integrated circuit (IC).

9. The device as claimed in claim 1, wherein the PWM controller is an ISL6333 IC.

10. The device as claimed in claim 1, further comprising an analog/digital (A/D) converter, the hot-swap control unit and the PWM controller connected to the processor via the A/D converter, the A/D converter converting the input current value and the output current value to digital signals and transmitting the digital signals to the processor.

11. The device as claimed in claim 1, further comprising a display module connected to the processor for displaying the value of the power efficiency of the power supply device.

12. A method for measuring power efficiency of a power supply device, comprising:
detecting values of a current and a voltage input to the power supply device;
detecting values of a current and a voltage output by the power supply device; and
calculating a value of the power efficiency of the power supply device according to the values of the current and the voltage input to the power supply device and the values of the current and the voltage output by the power supply device

13. The method as claimed in claim 12, wherein the value of the current input to the power supply device is detected by an LTC4218 IC, and the value of the voltage input to the power supply device is calculated according to the value of the current input to the power supply device.

14. The method as claimed in claim 12, wherein the value of the current output by the power supply device is detected by an ISL6333 IC, and the value of the voltage output by the power supply device is calculated according to the value of the current output by the power supply device.

15. The method as claimed in claim 12, further comprising displaying the value of the power efficiency of the power supply device.

16. The method as claimed in claim 12, further comprising preventing the current input to the power supply device from being provided to the power supply device when the value of the current input to the power supply device exceeds a predetermined value.
